(19) United States
(12) Patent Application Publication
(10) Pub. No.: US 2026/0215012 A1
(43) Pub. Date: Jul. 23, 2026

(54) SOLID-STATE IMAGING DEVICE WITH LIGHT-PATH CONVERSION MEMBER

(71) Applicant: Samsung Electronics Co., Ltd., Suwon-si (KR)

(72) Inventors: Masaru Kawabata, Yokohama (JP); Kazufumi Shiozawa, Yokohama (JP)

(21) Appl. No.: 19/454,047

(22) Filed: Jan. 20, 2026

(30) Foreign Application Priority Data
Jan. 21, 2025 (JP) 2025-008147
Dec. 10, 2025 (KR) 10-2025-0195627

(51) Int. Cl. H10F 39/00; H10F 39/18

(52) U.S. Cl. CPC H10F 39/8053; H10F 39/182; H10F 39/8063; H10F 39/8067

(57) ABSTRACT

A solid-state imaging device includes an on-chip lens, a color filter, a photodiode, a light-path conversion member on an incident surface of the color filter between the on-chip lens and the color filter, and a reflector on a lateral surface of the color filter. The light-path conversion member includes plurality of diffraction elements configured to change a light path of at least absorption light of the incident light toward the reflector, and the reflector is configured to reflect absorption light toward the color filter.

### CROSS-REFERENCE TO RELATED APPLICATIONS

This application is based on and claims priority under 35 U.S.C. § 119 to Japanese Patent Application No. 2025-008147, filed on Jan. 21, 2025, in the Japanese Intellectual Property Office, and to Korean Patent Application No. 10-2025-0195627, filed on Dec. 10, 2025, in the Korea Patent Office, the disclosures of which are incorporated by reference herein in their entirety.

### TECHNICAL FIELD

The disclosure relates to a solid-state imaging device.

### BACKGROUND

Electronic devices having an imaging function, such as digital still cameras or smartphones, use a solid-state imaging device, such as a complementary metal-oxide-semiconductor (CMOS) image sensor, etc. Recently, with the miniaturization of the electronic devices, the solid-state imaging device has been required to be miniaturized. As a method of miniaturizing a solid-state imaging device by forming a reduced device profile of the solid-state imaging device, a method of thinly forming a color filter, which is a component of the solid-state imaging device, may be considered. However, a layer thickness of the color filter may be determined to be associated with an absorption coefficient of a material to absorb light of a predefined wavelength, and desired spectral properties may be obtained by absorbing light, based on the light path length when the light travels in a direction perpendicular to a direction of the layer thickness of the color filter. Thus, it is required to form the color filter of the solid-state imaging device to have a certain thickness so as to properly disperse incident light.

### SUMMARY

The disclosure provides a solid-state imaging device having a reduced device profile, e.g., a reduced thickness, by including a color filter which is thinly formed while maintaining spectral properties thereof.

According to an aspect of the disclosure, there is provided a solid-state imaging device having a pixel array in which a plurality of pixels are two-dimensionally arranged on a chip substrate, the solid-state imaging device including an on-chip lens configured to focus incident light to each of the plurality of pixels, a color filter configured to absorb light of a predefined wavelength that is transmitted through the on-chip lens, a photodiode configured to photo-electrically convert the light transmitted through the color filter, a light-path conversion member having light transmissivity and formed on an incident surface of the color filter between the on-chip lens and the color filter, and a reflective structure arranged on a lateral surface of the color filter, the lateral surface being an edge between the color filter and another color filter adjacent to the color filter, wherein the light-path conversion member includes one or more diffraction elements configured to change a light path of at least absorption light of the incident light, the absorption light being absorbed by the color filter, toward the reflective structure, and the reflective structure is configured to reflect, toward the color filter, the absorption light having the light path changed by the light-path conversion member so that the absorption light has a light path length, which ensures that the absorption light is absorbable by the color filter.

According to another aspect of the disclosure, there is provided a solid-state imaging device including a pixel array including a plurality of pixels arranged in a matrix, wherein each of the plurality of pixels includes an on-chip lens configured to focus incident light, a color filter arranged below the on-chip lens and configured to absorb light of a first wavelength band, a photodiode configured to photo-electrically convert the light transmitted through the color filter, a light-path conversion member formed on an incident surface of the color filter between the on-chip lens and the color filter and including diffraction elements arrayed in a direction parallel to the incident surface, and a reflective structure arranged on a lateral surface of the color filter.

### BRIEF DESCRIPTION OF THE DRAWINGS

Implementations will be more clearly understood from the following detailed description taken in conjunction with the accompanying drawings.

FIG. 1A is a block diagram of a solid-state imaging device according to some implementations.

FIG. 1B is an enlarged partial plan view of a solid-state imaging device taken in a horizontal direction, according to some implementations.

FIG. 2 is a schematic cross-sectional view of a portion taken from a solid-state imaging device according to some implementations.

FIGS. 3A to 3G are schematic views of a shape of a diffraction device implemented in a light-path conversion member, according to some implementations.

FIGS. 4A, 4B, and 4C are views for describing a size condition of a diffraction device implemented in a light-path conversion member, according to some implementations.

FIGS. 5A, 5B, 5C, and 5D are views for describing Equation 1 to Equation 3.

FIG. 6A is a schematic view of a pixel located on a central side of a pixel array.

FIG. 6B is a schematic view of a pixel located on an outer peripheral side of a pixel array, the pixel being of the same color as the pixel of FIG. 6A.

FIG. 7A is a schematic view of a red pixel, a green pixel, and a blue pixel which are at the same image height on a central side of a pixel array.

FIG. 7B is a schematic view of a red pixel, a green pixel, and a blue pixel which are at the same height on an outer peripheral side of a pixel array.

FIG. 8A is a schematic cross-sectional view of a shape of a reflective structure.

FIG. 8B is a schematic cross-sectional view of a shape of a reflective structure.

FIG. 9A is a schematic view of a light path of incident light to a solid-state imaging device.

FIG. 9B is a schematic view of a light path of incident light to a solid-state imaging device.

FIG. 9C is a schematic view of a light path of incident light to a solid-state imaging device.

FIG. 10A is a ray-trace diagram of a blue pixel, in which a pitch of an array of a light-path conversion member is 400 nm, according to some implementations.

FIG. 10B is a ray-trace diagram of a blue pixel, in which a pitch of an array of a light-path conversion member is 500 nm, according to some implementations.

FIG. 10C is a ray-trace diagram of a blue pixel, in which a pitch of an array of a light-path conversion member is 600 nm, according to some implementations.

FIG. 10D is a ray-trace diagram of a green pixel, in which a pitch of an array of a light-path conversion member is 400 nm, according to some implementations.

FIG. 10E is a ray-trace diagram of a green pixel, in which a pitch of an array of a light-path conversion member is 500 nm, according to some implementations.

FIG. 10F is a ray-trace diagram of a green pixel, in which a pitch of an array of a light-path conversion member is 600 nm, according to some implementations.

FIG. 10G is a ray-trace diagram of a red pixel, in which a pitch of an array of a light-path conversion member is 400 nm, according to some implementations.

FIG. 10H is a ray-trace diagram of a red pixel, in which a pitch of an array of a light-path conversion member is 500 nm, according to some implementations.

FIG. 10I is a ray-trace diagram of a red pixel, in which a pitch of an array of a light-path conversion member is 600 nm, according to some implementations.

FIG. 11A is a schematic view of light paths of transmission light and absorption light of a blue pixel, in which a pitch of an array of a light-path conversion member is 400 nm, according to some implementations.

FIG. 11B is a schematic view of light paths of transmission light and absorption light of a green pixel, in which a pitch of an array of a light-path conversion member is 500 nm, according to some implementations.

FIG. 11C is a schematic view of light paths of transmission light and absorption light of a red pixel, in which a pitch of an array of a light-path conversion member is 600 nm, according to some implementations.

### DETAILED DESCRIPTION

Hereinafter, implementations will be described in detail with reference to the accompanying drawings. In the drawings below, like reference numerals refer to like elements, and a size of each component in the drawings may be exaggerated for clarity and convenience of explanations. Also, the implementations described hereinafter are only examples, and various changes from the implementations are possible.

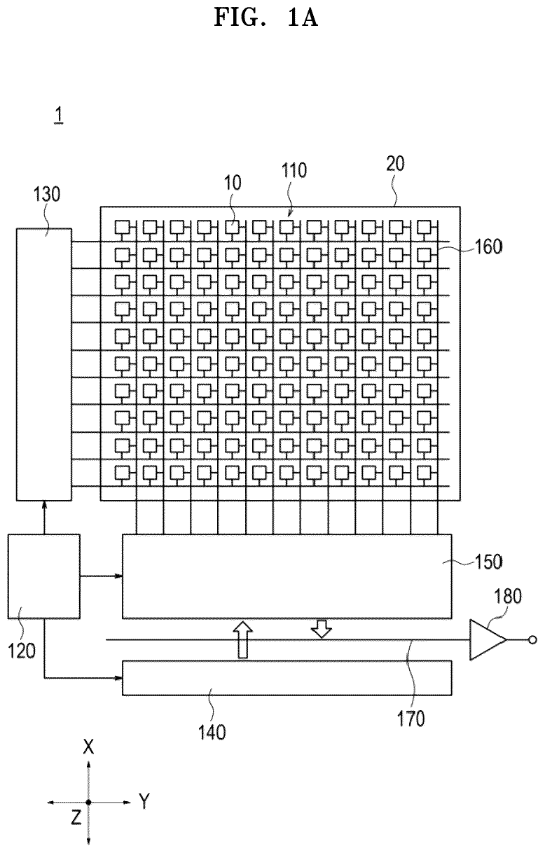

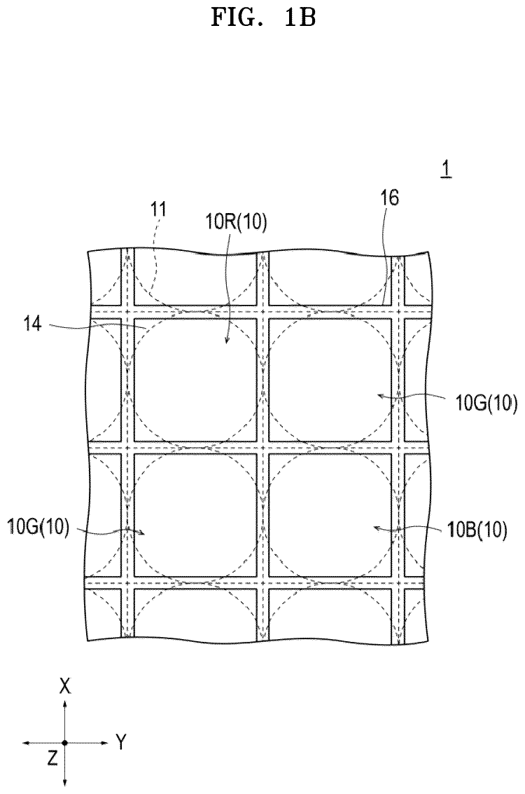

FIG. 1A is a block diagram of a solid-state imaging device 1 according to some implementations. For convenience of explanation, an XYZ orthogonal coordinate system is set on the solid-state imaging device 1. A direction parallel to an X axis on a certain plane is referred to as an X axis direction. A direction parallel to a Y axis orthogonal to the X axis on the certain plane is referred to as a Y axis direction. A direction parallel to a Z axis orthogonal to each of the X axis and the Y axis is referred to as a Z axis direction. According to the present implementations, the certain plane is parallel to a horizontal plane of an XY plane, and the Z axis is in a perpendicular direction orthogonal to the certain plane. Thus, the Z axis direction corresponds to a direction in which each of elements included in the solid-state imaging device 1 is stacked (a thickness direction), and the X axis direction and the Y axis direction correspond to directions of planes orthogonal to the direction in which each element is stacked.

The solid-state imaging device 1 may include a pixel 10 and a chip substrate 20. The solid-state imaging device 1 may be implemented as a complementary metal-oxide-semiconductor (CMOS) image sensor. The solid-state imaging device 1 may be referred to as an image sensor.

As illustrated in FIG. 1A, the solid-state imaging device 1 may include: a pixel array 110 including a plurality of pixels 10 configured to output a pixel signal to the chip substrate 20; a control circuit 120 configured to generate an operation signal for operating each of components of the solid-state imaging device 1; a vertical driving circuit 130 configured to scan each pixel 10 in a vertical direction (the Y axis direction in the drawing) and control the outputting of the pixel signal by each pixel 10 according to the amount of light received; a horizontal driving circuit 140 configured to output a scan pulse in a horizontal direction (the X axis direction in the drawing); a column signal processing circuit 150 configured to process the pixel signal output from each pixel 10 and generate an image signal; a vertical signal line 160 configured to transmit the pixel signal generated from each pixel 10 to the column signal processing circuit 150; a horizontal signal line 170 configured to output the image signal from the column signal processing circuit 150; and an output circuit 180 configured to process the image signal received through the horizontal signal line 170 and output the processed image signal.

The chip substrate 20 may include silicon, etc., and the plurality of pixels 10 may be formed on the chip substrate 20. A photoelectric conversion portion 14 may be formed on the chip substrate 20, and a pixel transistor, an interconnect layer, or the like, not shown, may be formed on a surface opposite to an incident surface of light (hereinafter, also referred to as “incident light L”) incident onto the solid-state imaging device 1. The chip substrate 20 may output a pixel signal generated by converting, into an electrical signal, the incident light L received from the photoelectric conversion portion 14.

The solid-state imaging device 1 may arbitrarily or optionally employ components well-known in the art, in addition to the pixel 10. Thus, in this specification, descriptions about the components other than the pixel 10 are appropriately omitted

FIG. 1B is an enlarged partial plan view of the solid-state imaging device 1 taken in the horizontal direction (taken by the XY plane), according to some implementations. As illustrated in FIG. 1B, the solid-state imaging device 1 may include the plurality of pixels 10 including a red pixel 10R, a green pixel 10G, and a blue pixel 10B. The plurality of pixels 10 may be arranged on the chip substrate 20 in a two-dimensional shape (for example, in a matrix shape) to form the pixel array 110. The arrangement of the pixels 10 may be appropriately set according to the specifications of the solid-state imaging device 1.

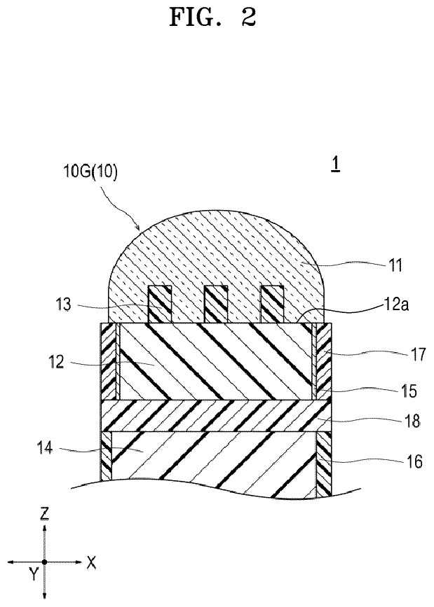

FIG. 2 is a schematic cross-sectional view of a portion of the solid-state imaging device 1, according to some implementations. In detail, FIG. 2 illustrates a cross-sectional surface of the pixel 10.

As illustrated in FIG. 2, the pixel 10 may include an on-chip lens 11 (or referred to as a micro lens), a color filter 12, a light-path conversion member 13, the photoelectric conversion portion 14, and a reflective structure 15. Sequentially from an incidence side of light (hereinafter, also referred to as incident light L) incident into the pixel 10, the on-chip lens 11, the color filter 12, the light-path conversion member 13, the photoelectric conversion portion 14, and the reflective structure 15 may be arranged. Also, the pixel 10 may include an isolation wall 16 separating the photoelectric conversion portion 14 for each pixel, a partition wall portion 17 separating the color filter 12 for each pixel, and an anti-reflection layer 18 arranged between the color filter 12 and the photoelectric conversion portion 14.

The on-chip lens 11 may be formed on the color filter 12. The on-chip lens 11 may be arranged to correspond to each unit pixel. For example, the on-chip lens 11 may be arranged on a plane two dimensionally (for example, in a matrix shape). The on-chip lens 11 may have a convex shape so that the incident light L may be focused at the photoelectric conversion portion 14, and the on-chip lens 11 may have a certain radius of curvature. The on-chip lens 11 may be formed by including organic materials, for example, styrene-based resins, acryl-based resins, styrene-acryl-copolymer resins, or siloxane-based resins.

The color filter 12 may be formed above the photoelectric conversion portion 14. The color filter 12 may be arranged two-dimensionally (for example, in a matrix shape) to correspond to each unit pixel. The color filter 12 may be implemented as various filters for each unit pixel. For example, the color filter 12 may be arranged as a Bayer pattern including a red color filter, a green color filter, and a blue color filter. However, this is only an example, and the color filter 12 may include a yellow filter, a magenta filter, and a cyan filter, and may additionally include a white filter.

The light-path conversion member 13 may be transmissive, may be arranged between the on-chip lens 11 and the color filter 12, and may curve a light path of the incident light L transmitted through the on-chip lens 11 to a certain direction. With respect to an incident surface 12a of the color filter 12, the incident surface 12a being an edge between the on-chip lens 11 and the color filter 12, the light-path conversion member 13 may extend toward the on-chip lens 11 in a direction of a normal line of the incident surface 12a.

The light-path conversion member 13 may change a light path of at least absorption light L1 from the incident light L incident to the color filter 12, the absorption light L1 having a predefined wavelength absorbed by the corresponding color filter 12, so that the absorption light L1 may proceed toward the reflective structure 15. Thus, the light-path conversion member 13 may change a light path of part or all of transmission light L2 (light transmitted well through the photoelectric conversion portion 14), which is included in the incident light L and an object of photoelectric conversion. Also, the light-path conversion member 13 may curve only the light path of the absorption light L1 in a certain direction, when the incident transmission light L2 proceeds straight in the thickness direction of the color filter 12. Because the light-path conversion member 13 is configured to curve only the absorption light L1 of the corresponding color filter 12 toward the reflective structure 15 and allow the transmission light L2 to proceed straight to the photoelectric conversion portion 14, the color filter 12 may be most thinly formed.

The light-path conversion member 13 may include a transmissive material, which may be implemented in the solid-state imaging device 1 and is known in the art (for example, a material which may be used in a manufacturing process of the solid-state imaging device 1). The light-path conversion member 13 may include the same material as the color filter 12. The light-path conversion member 13 may include a dielectric. The light-path conversion member 13 may include one or more diffraction elements arranged in a two-dimensional direction (an XY direction) on the incident surface 12a of the color filter 12. In addition thereto, the light-path conversion member 13 may also include one or more optical devices, such as a prism, etc. configured to allow the incident light L to proceed straight or to refract the incident light L according to a wavelength of the incident light L. The light-path conversion member 13 may be configured to curve the light path of the absorption light L1 included in the incident light L into the color filter 12 and change the light path of the absorption light L1.

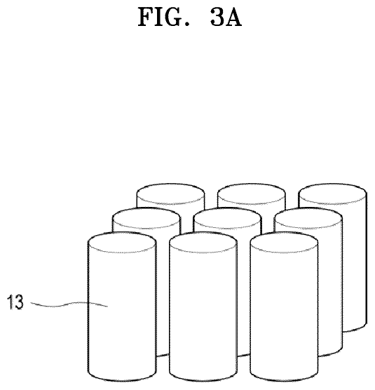

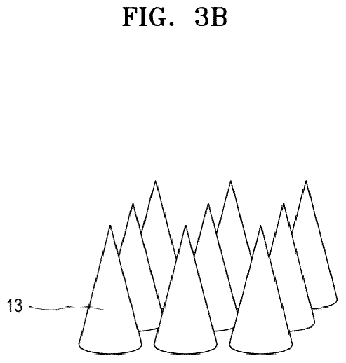

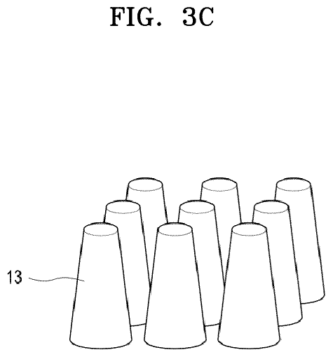

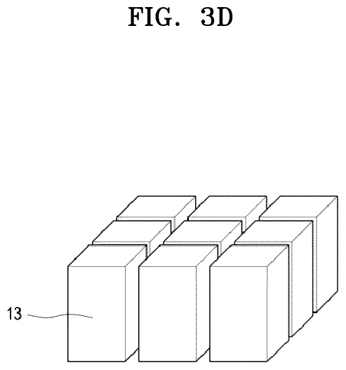

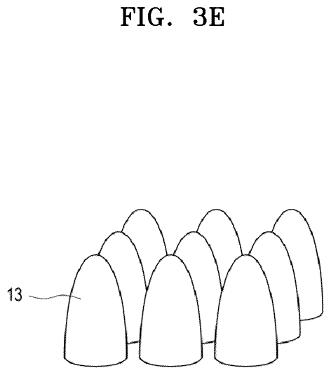

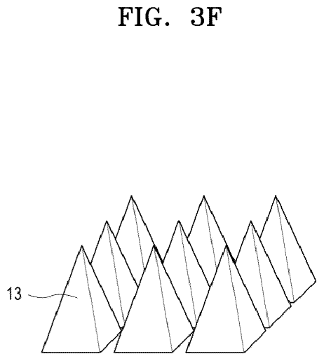

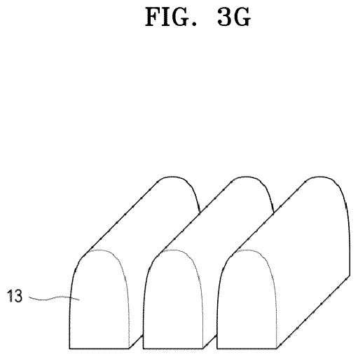

FIGS. 3A to 3G are schematic views of shapes of diffraction elements implemented in the light-path conversion member 13, according to some implementations.

The light-path conversion member 13 may implement the diffraction elements having various shapes as illustrated in FIGS. 3A to 3G. However, the light-path conversion member 13 is not limited to the shapes illustrated in FIGS. 3A to 3G.

The light-path conversion member 13 may include protruding diffraction elements having a cylindrical shape, as illustrated in FIG. 3A.

The light-path conversion member 13 may include protruding diffraction elements having a conical shape, as illustrated in FIG. 3B.

The light-path conversion member 13 may include protruding diffraction elements having a truncated conical shape, as illustrated in FIG. 3C.

The light-path conversion member 13 may include protruding diffraction elements having a rectangular cylindrical shape, as illustrated in FIG. 3D.

The light-path conversion member 13 may include protruding diffraction elements having a pyramidal shape, as illustrated in FIG. 3E. The shape illustrated in FIG. 3E may also be referred to as a shape having a so called “moth eye structure.”

The light-path conversion member 13 may include protruding diffraction elements having a quadrangular pyramidal shape (a so called pyramid shape), as illustrated in FIG. 3F.

The light-path conversion member 13 may include bar-shaped diffraction elements having a semi-elliptical cross-sectional shape (a so called semi-circular shape) and extending onto the incident surface 12a (on the XY plane) of the color filter 12, as illustrated in FIG. 3G.

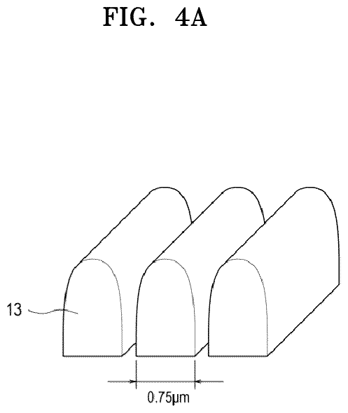

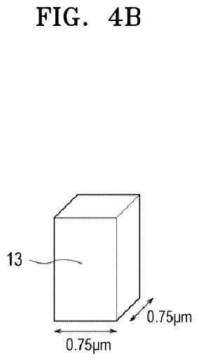

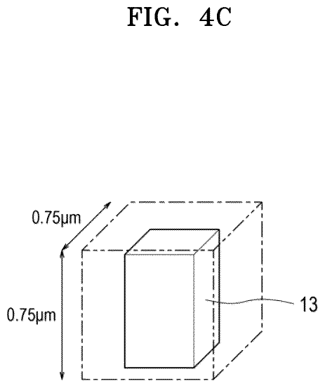

The sizes of the light-path conversion member 13 may be set to be associated with a wavelength range (for example, a wavelength of about 350 nm to about 780 nm) of visible light. The light-path conversion member 13 may be formed in the shapes as illustrated in FIGS. 4A to 4C.

As illustrated in FIG. 4A, the light-path conversion member 13 may be formed such that at least one side of a contact surface of the light-path conversion member 13 with respect to the incident surface 12a of the color filter 12 has a size of 0.75 μm or less. The shape illustrated in FIG. 4A may be implemented by the bar-shaped diffraction elements, etc., extending along the incident surface 12a of the color filter 12, as illustrated in FIG. 3G.

As illustrated in FIG. 4B, the light-path conversion member 13 may be formed such that a contact surface of the light-path conversion member 13 with respect to the incident surface 12a of the color filter 12 has an area which is less than an area of a square having a horizontal length and a vertical length each being 0.75 μm) (an area included in the square having the horizontal length and the vertical length each being 0.75 μm). The shape illustrated in FIG. 4B may be implemented by, for example, the diffraction elements illustrated in FIGS. 3B to 3F, in addition to the diffraction elements illustrated in FIG. 3A.

As illustrated in FIG. 4C, the light-path conversion member 13 may be formed to have a size that fits within a cube having a horizontal length and a vertical length each being 0.75 μm (a size less than the size of the cube having a horizontal length and a vertical length each being 0.75 μm). The shape illustrated in FIG. 4C may be implemented by, for example, the diffraction elements illustrated in FIGS. 3B to 3F, in addition to the diffraction elements illustrated in FIG. 3A.

The light-path conversion member 13 may be formed to have a varying size according to each color filter to correspond to the transmission light L2 of the color filter. For the blue color filter 12B, the light-path conversion member 13 may be formed to have a size less than a size of a cube having a horizontal length, a vertical length and a depth each being 0.55 μm. For the green color filter 12G, the light-path conversion member 13 may be formed to have a size less than the size of a cube having a horizontal length, a vertical length and a depth each being 0.65 μm. For the red color filter 12R, the light-path conversion member 13 may be formed to have a size less than the size of a cube having a horizontal length, a vertical length and a depth each being 0.75 μm.

The bottom area of the light-path conversion member 13 may be configured to satisfy a designed wavelength×a designed wavelength×0.5. That is, the bottom area of the light-path conversion member 13 may be the same as an area corresponding to the designed wavelength×the designed wavelength×0.5. For example, when the designed wavelength is 550 nm, the bottom area of the light-path conversion member 13 may be 550 nm×550 nm×0.5-390 nm×390 nm-220 nm×220 nm×π, and for example, the bottom area of the light-path conversion member 13 may be set to be a square having a side of 390 nm or a circle having a radius of 220 nm. Also, the height of the light-path conversion member 13 may be set to be the same as the designed wavelength.

The light-path conversion member 13 may be arrayed, on the incident surface 12a of the color filter 12, at a certain pitch, according to a type of the color filter 12. Also, the light-path conversion member 13 may have a height adjusted according to a type of the corresponding color filter 12 or an image height from the center of the pixel array 110 (for example, the radius from the center of the pixel array 110).

Also, when the light-path conversion member 13 is configured to change a light path of at least the absorption light L1 included in the incident light L toward the reflective structure 15 located on a lateral surface of the color filter 12, shapes of the light-path conversion member 13 or the number of arrayed light-path conversion members 13 is not particularly limited.

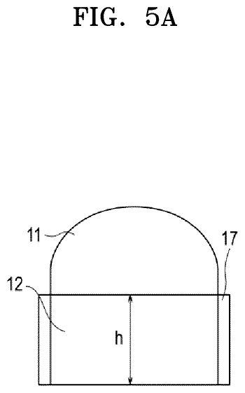

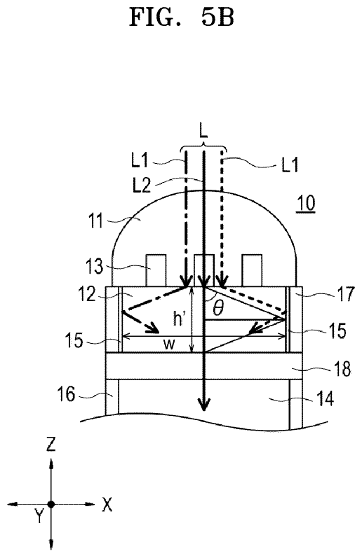

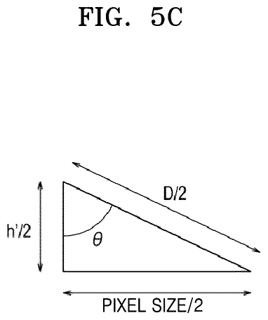

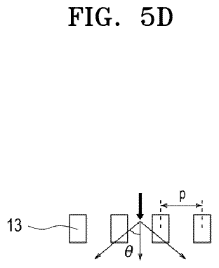

The light-path conversion member 13 may be arranged on the entire incident surface 12a of the color filter 12 in the pixel 10 at a certain interval. Also, when the incident light L is incident onto only a portion of the incident surface 12a of the color filter 12 due to a focusing effect of the on-chip lens 11, the light-path conversion member 13 may be arranged at only the portion of the incident surface 12a, onto which the incident light L is incident. That is, the light-path conversion member 13 may be arranged at a location which may be covered by at least an incident area of the incident light L that is incident to the pixel 10. FIG. 5A illustrates a solid-state imaging device according to comparative implementations, FIG. 5B illustrates the solid-state imaging device 1 according to the present implementations, FIG. 5C is a view for describing an equation for determining a layer thickness h′ of the solid-state imaging device 1 according to the present implementations, and FIG. 5D is a view for describing an equation for determining a pitch of an array P of the solid-state imaging device 1 according to the present implementations.

As illustrated in FIG. 5A a layer thickness of the color filter 12 of the solid-state imaging device according to the comparative implementations may be set to be ‘h.’ As illustrated in FIG. 5B, the thickness direction (a layer thickness) of the color filter 12 in the Z axis direction according to the present implementations may be set to be “h′,” the width (a pixel size) of the color filter 12 in the X axis direction according to the present implementations may be set to be “w,” and a proceeding angle (for example, a tilt angle with respect to an optical axis) of diffraction light may be set to be “θ.” Also, as illustrated in FIGS. 5C and 5D, a wavelength of the incident light L may be set to be “λ,” an order of diffraction of the incident light L may be set to be “m,” an angle of incidence of the incident light L may be set to be “θ1,” an angle of emergence (a refractive angle) of the incident light L may be set to be “θ2,” a refractive index of a medium of an incidence side may be set to be “n1,” a refractive index of a medium of an emergence side may be set to be “n2,” and a light path length of the diffraction light may be set to be “D.” Then, the layer thickness h′ of the color filter 12 may be obtained based on Equation 1 and Equation 3 described below, and the pitch of the array P of the light-path conversion member 13 may be obtained based on Equation 2 and Equation 3 described below. Here, the proceeding angle θ of the diffraction light may be the same as the angle of emergence θ2.

$$tan θ = w / {h}^{′} \qquad [ Equation 1 ]$$

$$sin θ = w / D \qquad [ Equation 2 ]$$

$$n 1 \times sin θ1 \pm m λ / P = n 2 \times sin θ 2 \qquad [ Equation 3 ]$$

For example, when the angle of incidence is 0° (a direction of a normal line of the incident surface 12a) and m=1, sin θ=λ/(P×n2). As illustrated in FIGS. 5A and 5B, the solid-state imaging device 1 according to the present implementations may have the layer thickness h′ of the color filter 12, which is less than the layer thickness h of the color filter of the solid-state imaging device according to the comparative implementations. Also, the solid-state imaging device 1 may reflect the incident light L within the color filter 12 through the reflective structure 15. Thus, the light path length D of the incident light L of the solid-state imaging device 1 may become greater than a light path of the solid-state imaging device according to the comparative implementations. Thus, the solid-state imaging device 1 may absorb sufficient light even when the layer thickness of the color filter 12 is reduced.

In the solid-state imaging device 1, the layer thickness h′ of the color filter 12 and the pitch of the array P of the light-path conversion member 13 for each pixel 10 may be determined based on Equation 1 to Equation 3 described above. Thus, the solid-state imaging device 1 may allow proceeding of at least the absorption light L1 included in the incident light L incident to the pixel 10 by changing a light path of the absorption light L1 to have a length which may be absorbed in the color filter 12.

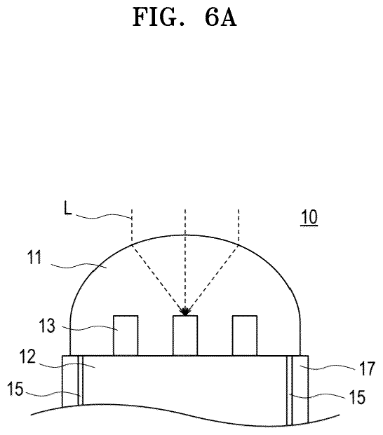

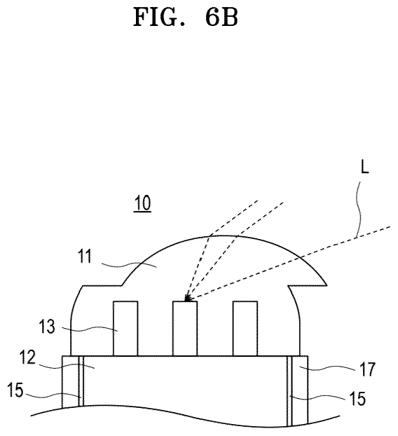

FIG. 6A is a schematic view of a pixel located on a central side of a pixel array, and FIG. 6B is a schematic view of a pixel located on an outer peripheral side of the pixel array, the pixel being of the same color as the pixel of FIG. 6A.

A pitch of an array of the light-path conversion member 13 may be set according to an angle of incidence of any one principal ray from an entrance pupil and an exit pupil of the on-chip lens 11. In the solid-state imaging device 1, an angle of incidence of a ray of a principal ray of the incident light L may be different between the central side and the outer peripheral side of the pixel array 110, wherein the angle of incidence of the ray increases toward the outer peripheral side of the pixel array 110. The pitch of the array of the light-path conversion member 13 arranged in the pixel 10 of the same color may increase from when the pixel 10 is arranged on the center of the pixel array 110 toward when the pixel 10 is arranged on the outer peripheral side of the pixel array 110, as illustrated in FIGS. 6A and 6B, in order to align a top surface of the light-path conversion member 13 to a focal position of the principal ray for each pixel 10. Thus, the pitch of the array of the light-path conversion member 13 may be greater in the pixel 10 on the outer peripheral side of the pixel array 110 than in the pixel 10 on the central side of the pixel array 110, the pixel 10 being of the same color. Here, the “principal ray” denotes some rays from the entire incident light L incident to the specific pixel 10 of the solid-state imaging device 1, the rays passing through an aperture center of any one of the entrance pupil and the exit pupil of the on-chip lens 11.

In the solid-state imaging device 1, the refractive index of a material of the on-chip lens 11, etc., may tend to increase as a wavelength becomes shorter. Also, a location at which the incident light L may form an image is distanced from an image plane, from the central side of the pixel array 110 toward the outer peripheral side of the pixel array 110, and the rays may converge at a front side of the image plane as the wavelength becomes shorter due to an effect of chromatic aberration. Thus, in the solid-state imaging device 1, the height of the light-path conversion member 13 of the pixel 10 at the same image height may increase in an order of a red pixel, a green pixel, and a blue pixel (a relationship of the heights of the light-path conversion member 13 among the pixels: the red pixel<the green pixel<the blue pixel). Also, the height of the light-path conversion member 13 arranged in the pixel 10 of the same color may increase from when the pixel 10 is arranged on the central side of the pixel array 110 toward when the pixel 10 is arranged on the outer peripheral side of the pixel array 110, as illustrated in FIGS. 6A and 6B. Thus, the height of the light-path conversion member 13 of the pixel 10 of the same color may be greater in the pixel 10 on the outer peripheral side of the pixel array 110 than in the pixel 10 on the central side of the pixel array 110.

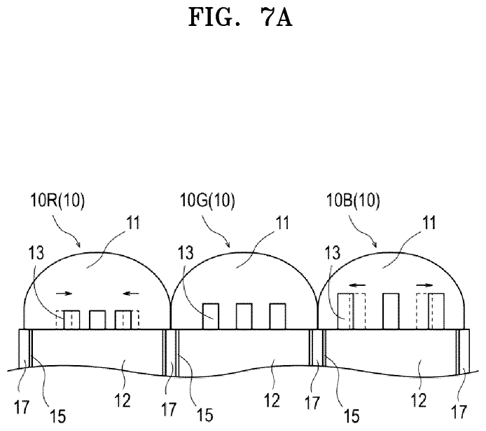

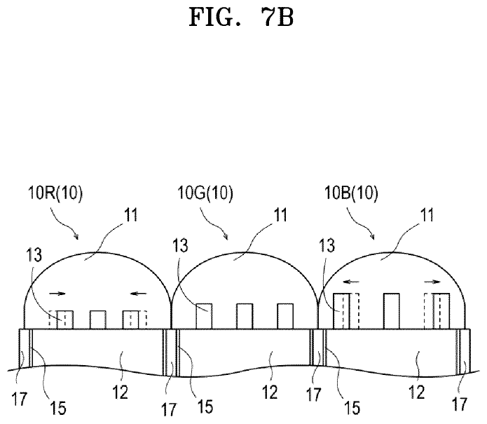

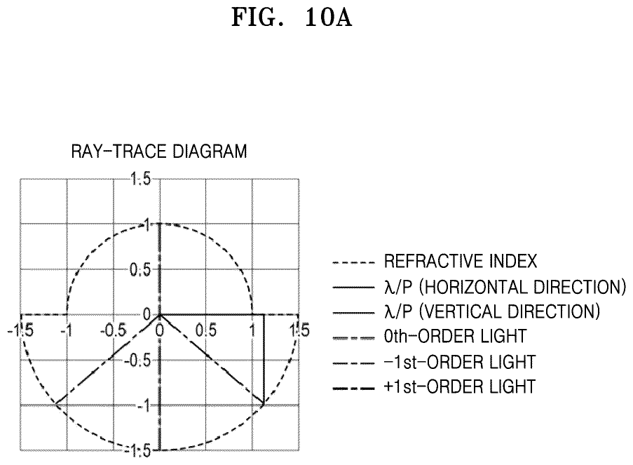

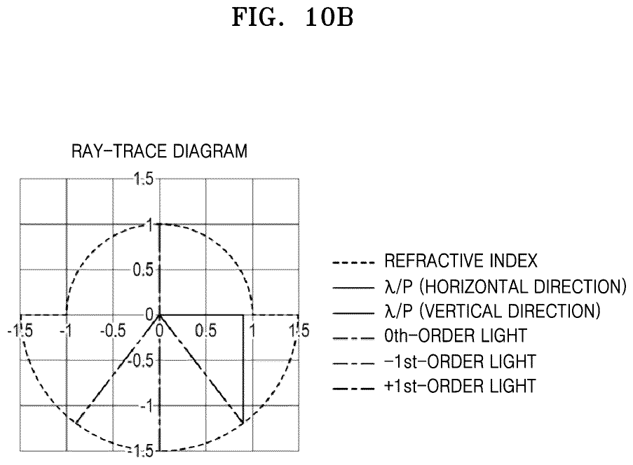

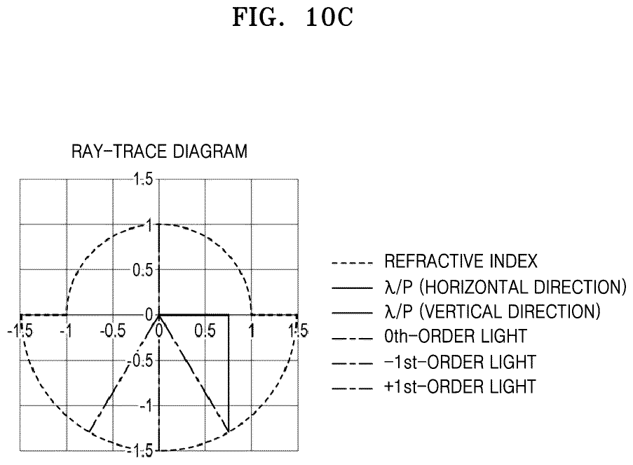

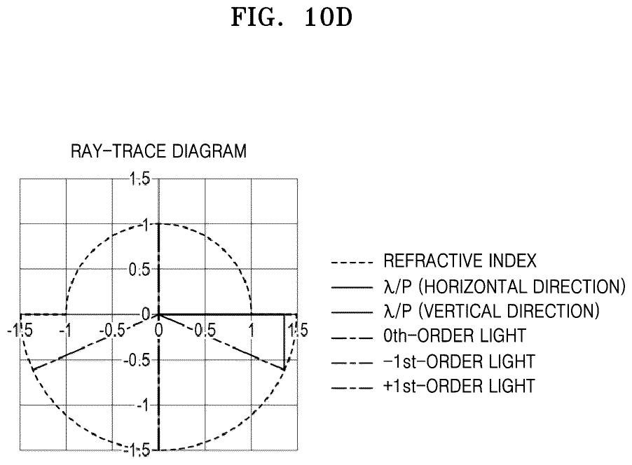

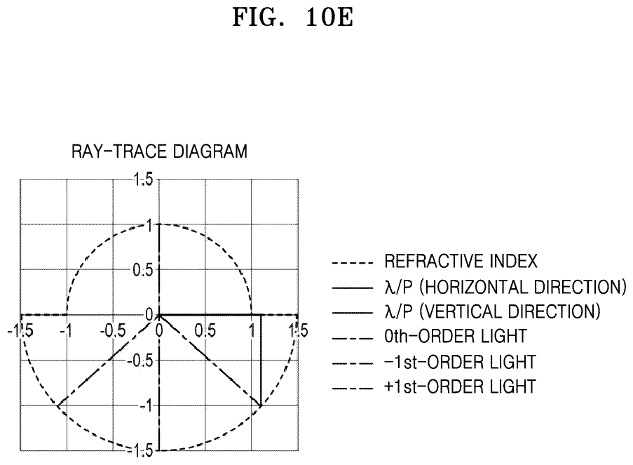

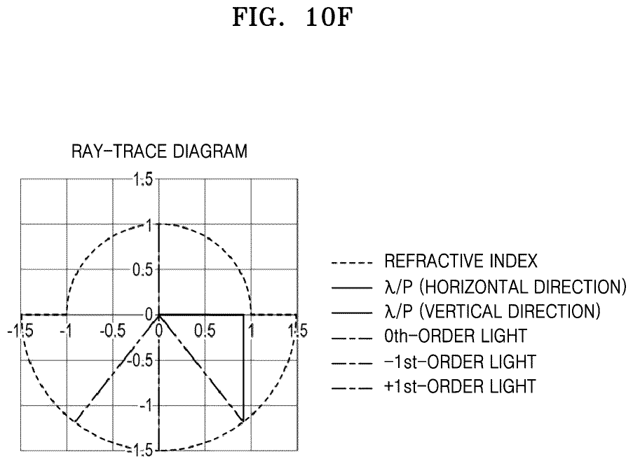

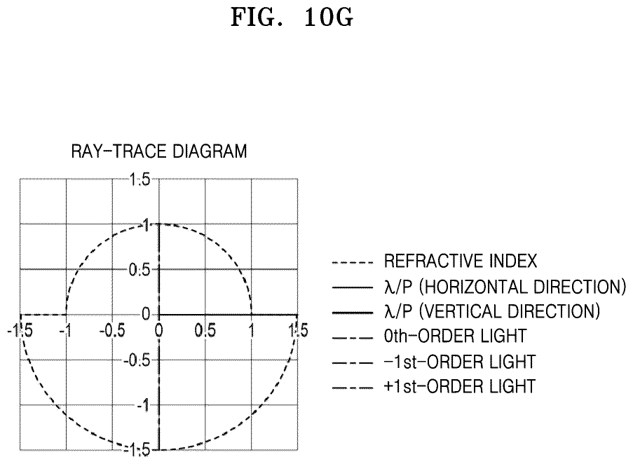

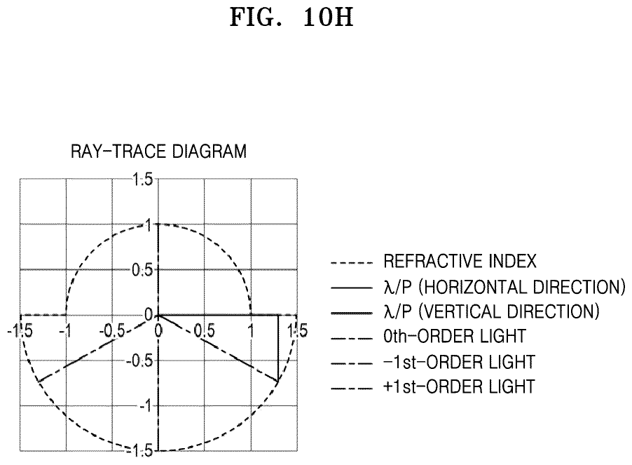

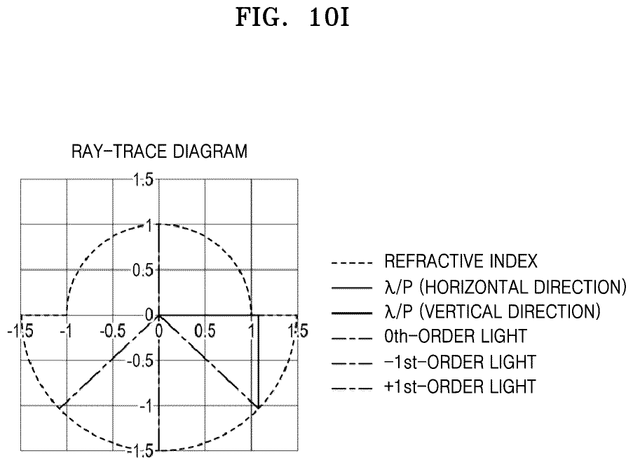

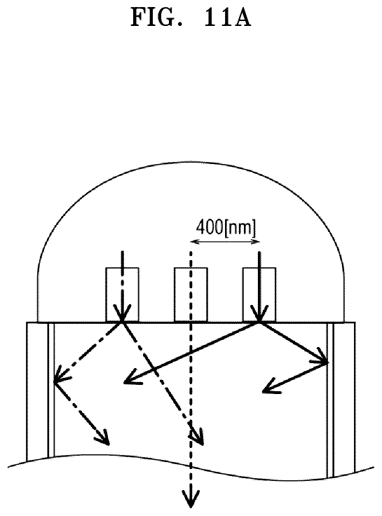

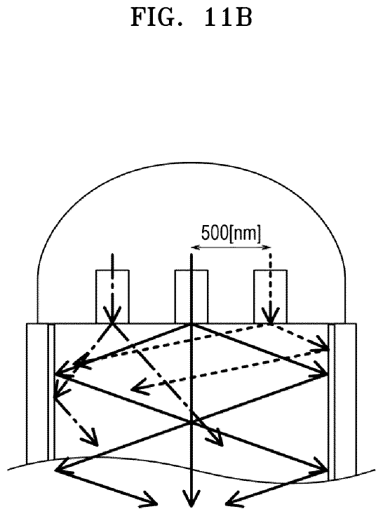

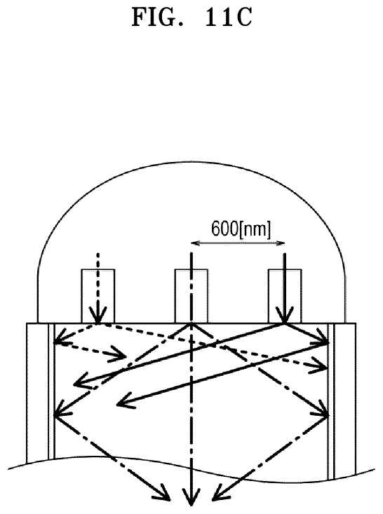

FIG. 7A is a schematic view of the red pixel, the green pixel, and the blue pixel located at the same image height on the central side of the pixel array 110. FIG. 7B is a schematic view of the red pixel, the green pixel, and the blue pixel located at the same image height on the outer peripheral side of the pixel array 110. In the solid-state imaging device 1, an angle of incidence of a ray of a principal ray may be different between the central side and the outer peripheral side of the pixel array 110, wherein the angle of incidence may increase towards the outer peripheral side of the pixel array 110. Thus, as illustrated in FIGS. 7A and 7B, when compared using the pixel of the same color, the pitch of the light-path conversion member 13 may increase in the case of the pixel at the outer peripheral side. Also, in the solid-state imaging device 1, the pitch of the array of the light-path conversion member 13 of the pixel 10 at the same image height may increase in an order of the red pixel, the green pixel, and the blue pixel as illustrated in FIGS. 7A and 7B (a size relationship of the pitch of the array among the pixels: the red pixel<the green pixel<the blue pixel). The reason for this will be described below with reference to FIGS. 10A to 10I and FIGS. 11A to 11C. Accordingly, the solid-state imaging device 1 may diffract the absorption light L1 for each pixel and obtain the light path length to be absorbed by the color filter 12.

The photoelectric conversion portion 14 may convert, into an electrical signal, the transmission light L2 of an object to be photo-electrically converted of the incident light L incident to the solid-state imaging device 1, the transmission light L2 proceeding to the photoelectric conversion portion 14. The photoelectric conversion portion 14 may be surrounded by the isolation wall 16 to be isolated between the adjacent pixels 10. The photoelectric conversion portion 14 may include, for example, at least one of a photodiode, a phototransistor, a photogate, a pinned photodiode, an organic photodiode, quantum dots, and a combination thereof, but is not limited thereto.

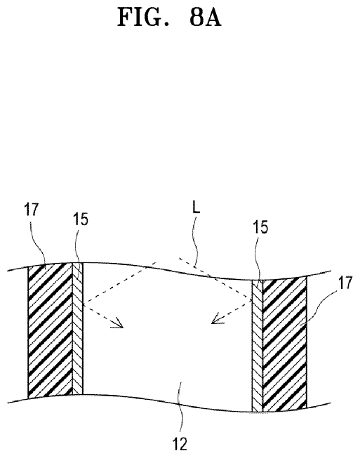

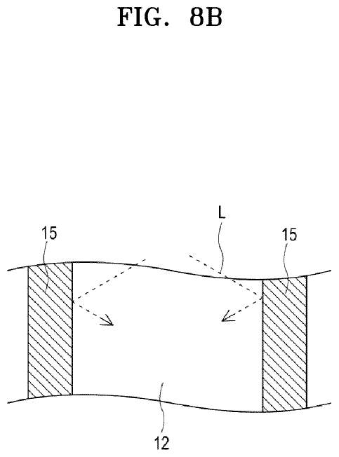

FIGS. 8A and 8B are schematic cross-sectional views of the shape of the reflective structure 15.

The reflective structure 15 may reflect the light having a light path changed by the light-path conversion member 13 toward the photoelectric conversion portion 14. The reflective structure 15 may be arranged on a lateral surface of the color filter 12, the lateral surface forming an edge with respect to another color filter 12 adjacent to the color filter 12. The reflective structure 15 may form a layer on an inner circumferential side of the partition wall portion 17, as illustrated in FIG. 8A. Alternatively, the reflective structure 15 may perform a function of the partition wall portion 17, as illustrated in FIG. 8B, and may be arranged to surround the pixel 10, rather than the partition wall portion 17.

The reflective structure 15 may include a member having a function of light reflection. The reflective structure 15 may include a form in which a reflection layer including MgF₂, etc. is formed on a surface of the partition wall portion 17, a form in which the partition wall portion 17 includes a metal reflecting plate including Au, Ag, Pt, etc., or the like.

The reflective structure 15 may be formed at a location to reflect the incident light L within the color filter 12 so that the light path of the absorption light L1 included in the incident light L may have a length which may be absorbed by the color filter 12. Therefore, the reflective structure 15 may be formed to surround the entire circumference of the pixel 10 or a portion of the pixel 10 in a plan view.

Next, referring to FIG. 5B, the isolation wall 16 may be formed as deep trench isolation (DTI). The isolation wall 16 may be formed to surround the photoelectric conversion portion 14 of the pixel 10, as illustrated in FIGS. 1B and 2. Thus, the photoelectric conversion portion 14 of the pixel 10 may be isolated from the photoelectric conversion portion 14 of another pixel 10 adjacent to the pixel 10. According to some implementations, the photoelectric conversion portion 14 of the pixel 10 may be entirely or partially isolated from the photoelectric conversion portion 14 of the other pixel 10 adjacent to the pixel 10.

The partition wall portion 17 may isolate the color filter 12 in the pixel 10 from another color filter 12 adjacent to and surrounding the color filter 12. The partition wall portion 17 may be arranged at an edge portion of the adjacent color filter 12. The partition wall portion 17 may be arranged in a lattice shape in a plan view, thereby being arranged between the plurality of color filters 12 and segmenting each pixel 10. The partition wall portion 17 may have a function of preventing the vignetting of at least the incident light L incident to the pixel 10 and a function of blocking light entering from the adjacent pixel 10. Thus, the partition wall portion 17 may be formed to have a height and a width to achieve these functions.

The anti-reflection layer 18 may be arranged between the color filter 12 and the photoelectric conversion portion 14. The anti-reflection layer 18 may be formed by alternately stacking a high refractive layer including a high refractive material (for example, SiN, HFO, TaO, TiO, etc.) and a low-refractive layer including a low-refractive material (SiO₂, AlO, etc.).

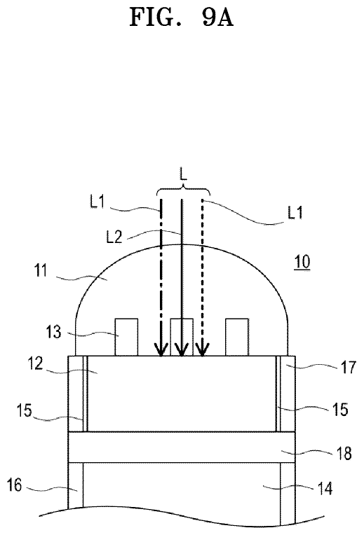

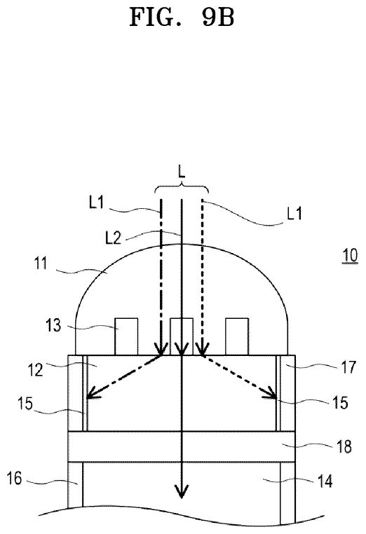

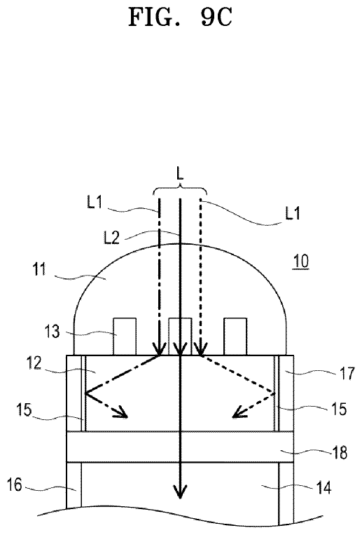

The solid-state imaging device 1 may have the structure as described above to perform the following functions. In the solid-state imaging device 1, when the incident light L is incident to the pixel 10, the incident light L may pass through the on-chip lens 11 and reach the light-path conversion member 13, as illustrated in FIG. 9A. As illustrated in FIG. 9B, when the incident light L is transmitted through the light-path conversion member 13, the light path of at least the absorption light L1 of the corresponding color filter 12 may be changed toward the reflective structure 15. As illustrated in FIG. 9C, the reflective structure 15 may reflect the light having the light path changed by the light-path conversion member 13 to the photoelectric conversion portion 14. Here, the absorption light L1 may be absorbed by the color filter 12 by securing the light path length to be absorbed by the color filter 12. Also, the transmission light L2 may be transmitted through the color filter 12 and photo-electrically converted by the photoelectric conversion portion 14.

As used herein, a “light path length” refers to the total physical distance that light, e.g., the absorption light L1, travels inside the color filter 12. Leveraging the described architecture, the light path length is increased to be greater than the layer thickness of the color filter 12. In other words, the described architecture allows the physical thickness to be reduced while maintaining a sufficiently long light path length to ensure the absorption light L1 is fully absorbed.

Absorption light L1 may represent unwanted light, and thus need to be absorbed, from the perspective of the photodiode because it includes wavelengths that do not correspond to the color assigned to that specific pixel. In a solid-state imaging device, pixels are assigned specific colors (red, green, or blue) to capture a color image. The absorption light is the light that belongs to the other color bands. For example, for a red pixel, the transmission light L2 is red light; the absorption light L1, i.e., the unwanted light, includes green and blue light.

As described above, the solid-state imaging device 1 may change the light path of the absorption light L1 included in the incident light L and reflect the absorption light L1 by using the reflective structure 15 so that the absorption light L1 may proceed to the photoelectric conversion portion 14. Thus, the absorption light L1 may be absorbed by the color filter 12 by securing the light path length to be absorbed by the corresponding color filter 12. Therefore, in the solid-state imaging device 1, the color filter 12 may be thinly formed while securing spectral properties. Thus, the solid-state imaging device 1 may be miniaturized and have a reduced device profile.

Next, a method of calculating a pitch of an array of the light-path conversion member 13 in the solid-state imaging device 1 is described. In the solid-state imaging device 1, the pitch of the array of the light-path conversion member 13 for each pixel 10 may be determined based on Equation 1 to Equation 3 described above, according to Implementation 1 to Implementation 4 hereinafter, and the light-path conversion member 13 may be two-dimensionally and periodically arrayed on the incident surface 12a of the color filter 12.

As used herein, a “pitch” of an array of diffraction elements refers to a periodic distance (spacing) between the diffraction elements within the array that is formed on top of the color filter 12. As will be explained further below, there can be an array of diffraction elements corresponding to each color, and the arrays of diffraction elements corresponding to the different colors have different pitches.

The solid-state imaging device 1 according to Implementation 1 may have the pixels 10 including the blue pixel 10B, the green pixel 10G, and the red pixel 10R. The horizontal width of each of the pixels 10 may be GH, and the vertical width of each of the pixels 10 may be GV. The color filter 12 may include the blue color filter 12B corresponding to the blue pixel 10B and having a refractive index of n2F of a wavelength of 486 nm and a thickness of CTB, the green color filter 12G corresponding to the green pixel 10G and having a refractive index of n2e of a wavelength of 546 nm and a thickness of CTG, and the red color filter 12R corresponding to the red pixel 10R and having a refractive index of n2C of a wavelength of 656 nm and thickness of CTR, and the color filter 12 may be arranged below the on-chip lens 11 in an incident direction of the incident light L. Here, the light-path conversion member 13 arranged in each pixel 10 may be two-dimensionally and periodically arrayed at a pitch satisfying Condition 1 to Condition 6 described below. Also, in Equation 4 to Equation 9, m is an integer.

In Condition 1, a horizontal pitch of the light-path conversion member 13 for the blue color filter 12B may have a central value CPBH of Pitch_BH satisfying Equation 4 below and may satisfy a range of about 0.8×CPBH to about 1.2×CPBH.

$$[ 1 + {( GH / CTB )}^{2} ] \times [ 1 - {\{ ( m \times 486 ) / ( n 2 F \times Pitch\_BH ) \}}^{2} ] = 1 \qquad [ Equation 4 ]$$

In Condition 2, a vertical pitch of the light-path conversion member 13 for the blue color filter 12B may have a central value CPBV of Pitch_BV satisfying Equation 5 below and may satisfy a range of about 0.8×CPBV to about 1.2×CPBV.

$$[ 1 + {( GV / CTB )}^{2} ] \times [ 1 - {\{ ( m \times 486 ) / ( n 2 F \times Pitch\_BV ) \}}^{2} ] = 1 \qquad [ Equation 5 ]$$

In Condition 3, a horizontal pitch of the light-path conversion member 13 for the green color filter 12G may have a central value CPGH of Pitch_GH satisfying Equation 6 below and may satisfy a range of about 0.8×CPGH to about 1.2×CPGH.

$$[ 1 + {( GH / CTG )}^{2} ] \times [ 1 - {\{ ( m \times 546 ) / ( n 2 e \times Pitch\_GH ) \}}^{2} ] = 1 \qquad [ Equation 6 ]$$

In Condition 4, a vertical pitch of the light-path conversion member 13 for the green color filter 12G may have a central value CPGV of Pitch_GV satisfying Equation 7 below and may satisfy a range of about 0.8×CPGV to about 1.2×CPGV.

$$[ 1 + {( GV / CTG )}^{2} ] \times [ 1 - {\{ ( m \times 546 ) / ( n 2 e \times Pitch\_GV ) \}}^{2} ] = 1 \qquad [ Equation 7 ]$$

In Condition 5, a horizontal pitch of the light-path conversion member 13 for the red color filter 12R may have a central value CPRH of Pitch_RH satisfying Equation 8 below and may satisfy a range of about 0.8×CPRH to about 1.2×CPRH.

$$[ 1 + {( GH / CTR )}^{2} ] \times [ 1 - {\{ ( m \times 656 ) / ( n 2 C \times Pitch\_RH ) \}}^{2} ] = 1 \qquad [ Equation 8 ]$$

In Condition 6, a vertical pitch of the light-path conversion member 13 for the red color filter 12R may have a central value CPRV of Pitch_RV satisfying Equation 9 below and may satisfy a range of about 0.8×CPRV to about 1.2×CPRV.

$$[ 1 + {( GV / CTR )}^{2} ] \times [ 1 - {\{ ( m \times 656 ) / ( n 2 C \times Pitch\_RV ) \}}^{2} ] = 1 \qquad [ Equation 9 ]$$

The solid-state imaging device 1 according to Implementation 2 may have the pixels 10 including the blue pixel 10B, the green pixel 10G, and the red pixel 10R. The horizontal width of each of the pixels 10 may be GH, and the vertical width of each of the pixels 10 may be GV. The color filter 12 may include the blue color filter 12B corresponding to the blue pixel 10B and having a wavelength λB of a blue area in a range of about 350 nm to about 500 nm, a refractive index of n2B in the wavelength λB, and a thickness of CTB, the green color filter 12G corresponding to the green pixel 10G and having a wavelength λG of a green area in a range of about 500 nm to about 600 nm, a refractive index of n2G in the wavelength λG, and a thickness of CTG, and the red color filter 12R corresponding to the red pixel 10R and having a wavelength XR of a red area in a range of about 600 nm to about 700 nm, a refractive index of n2R in the wavelength XR, and a thickness of CTR, and the color filter 12 may be arranged below the on-chip lens 11 in an incident direction of the incident light L. Here, the light-path conversion member 13 arranged in each pixel 10 may be two-dimensionally and periodically arrayed at a pitch satisfying Condition 7 to Condition 12 described below. Also, in Equation 10 to Equation 15, m is an integer.

In Condition 7, a horizontal pitch of the light-path conversion member 13 for the blue color filter 12B may have a central value CPBH of Pitch_BH satisfying Equation 10 below and may satisfy a range of about 0.8×CPBH to about 1.2×CPBH.

$$[ 1 + {( GH / CTB )}^{2} ] \times [ 1 - {\{ ( m \times λ B ) / ( n 2 B \times Pitch\_BH ) \}}^{2} ] = 1 \qquad [ Equation 10 ]$$

In Condition 8, a vertical pitch of the light-path conversion member 13 for the blue color filter 12B may have a central value CPBV of Pitch_BV satisfying Equation 11 below and may satisfy a range of about 0.8×CPBV to about 1.2×CPBV.

$$[ 1 + {( GV / CTB )}^{2} ] \times [ 1 - {\{ ( m \times λ B ) / ( n 2 B \times Pitch\_BV ) \}}^{2} ] = 1 \qquad [ Equation 11 ]$$

In Condition 9, a horizontal pitch of the light-path conversion member 13 for the green color filter 12G may have a central value CPGH of Pitch_GH satisfying Equation 12 below and may satisfy a range of about 0.8×CPGH to about 1.2×CPGH.

$$[ 1 + {( GH / CTG )}^{2} ] \times [ 1 - {\{ ( m \times λ G ) / ( n 2 G \times Pitch\_GH ) \}}^{2} ] = 1 \qquad [ Equation 12 ]$$

In Condition 10, a vertical pitch of the light-path conversion member 13 for the green color filter 12G may have a central value CPGV of Pitch_GV satisfying Equation 13 below and may satisfy a range of about 0.8×CPGV to about 1.2×CPGV.

$$[ 1 + {( GV / CTG )}^{2} ] \times [ 1 - {\{ ( m \times λ G ) / ( n 2 G \times Pitch\_GV ) \}}^{2} ] = 1 \qquad [ Equation 13 ]$$

In Condition 11, a horizontal pitch of the light-path conversion member 13 for the red color filter 12R may have a central value CPRH of Pitch_RH satisfying Equation 14 below and may satisfy a range of about 0.8×CPRH to about 1.2×CPRH.

$$[ 1 + {( GH / CTR )}^{2} ] \times [ 1 - {\{ ( m \times λ R ) / ( n 2 R \times Pitch\_RH ) \}}^{2} ] = 1 \qquad [ Equation 14 ]$$

In Condition 12, a vertical pitch of the light-path conversion member 13 for the red color filter 12R may have a central value CPRV of Pitch_RV satisfying Equation 15 below and may satisfy a range of about 0.8×CPRV to about 1.2×CPRV.

$$[ 1 + {( GV / CTR )}^{2} ] \times [ 1 - {\{ ( m \times λ R ) / ( n 2 R \times Pitch\_RV ) \}}^{2} ] = 1 \qquad [ Equation 15 ]$$

The solid-state imaging device 1 according to Implementation 3 may have the pixels 10 including the blue pixel 10B, the green pixel 10G, and the red pixel 10R. The horizontal width of each of the pixels 10 may be GH, and the vertical width of each of the pixels 10 may be GV. The color filter 12 may include the blue color filter 12B corresponding to the blue pixel 10B and having a wavelength λB of a blue area in a range of about 350 nm to about 500 nm and a refractive index of n2B in the wavelength λB, the green color filter 12G corresponding to the green pixel 10G and having a wavelength λG of a green area in a range of about 500 nm to about 600 nm and a refractive index of n2G in the wavelength λG, and the red color filter 12R corresponding to the red pixel 10R and having a wavelength XR of a red area in a range of about 600 nm to about 700 nm and a refractive index of n2R in the wavelength XR, and the color filter 12 may be arranged below the on-chip lens 11 in an incident direction of the incident light L. All of thicknesses of the blue color filter 12B, the green color filter 12G, and the red color filter 12R may be equal to the thickness CTR of the red color filter 12R. Here, the light-path conversion member 13 arranged in each pixel 10 may be two-dimensionally and periodically arrayed at a pitch satisfying Condition 13 to Condition 18 described below. Also, in Equation 16 to Equation 21, m is an integer.

In Condition 13, a horizontal pitch of the light-path conversion member 13 for the blue color filter 12B may have a central value CPBH of Pitch_BH obtained based on Equation 16 below and may satisfy a range of about 0.8×CPBH to about 1.2×CPBH.

$$[ 1 + {( GH / CTR )}^{2} ] \times [ 1 - {\{ ( m \times λ B ) / ( n 2 B \times Pitch\_BH ) \}}^{2} ] = 1 \qquad [ Equation 16 ]$$

In Condition 14, a vertical pitch of the light-path conversion member 13 for the blue color filter 12B may have a central value CPBV of Pitch_BV obtained based on Equation 17 below and may satisfy a range of about 0.8×CPBV to about 1.2×CPBV.

$$[ 1 + {( GV / CTR )}^{2} ] \times [ 1 - {\{ ( m \times λ B ) / ( n 2 B \times Pitch\_BV ) \}}^{2} ] = 1 \qquad [ Equation 17 ]$$

In Condition 15, a horizontal pitch of the light-path conversion member 13 for the green color filter 12G may have a central value CPGH of Pitch_GH obtained based on Equation 18 below and may satisfy a range of about 0.8×CPGH to about 1.2×CPGH.

$$[ 1 + {( GH / CTR )}^{2} ] \times [ 1 - {\{ ( m \times λ G ) / ( n 2 G \times Pitch\_GH ) \}}^{2} ] = 1 \qquad [ Equation 18 ]$$

In Condition 16, a vertical pitch of the light-path conversion member 13 for the green color filter 12G may have a central value CPGV of Pitch_GV obtained based on Equation 19 below and may satisfy a range of about 0.8×CPGV to about 1.2×CPGV.

$$[ 1 + {( GV / CTR )}^{2} ] \times [ 1 - {\{ ( m \times λ G ) / ( n 2 G \times Pitch\_GV ) \}}^{2} ] = 1 \qquad [ Equation 19 ]$$

In Condition 17, a horizontal pitch of the light-path conversion member 13 for the red color filter 12R may have a central value CPRH of Pitch_RH obtained based on Equation 20 below and may satisfy a range of about 0.8×CPRH to about 1.2×CPRH.

$$[ 1 + {( GH / CTR )}^{2} ] \times [ 1 - {\{ ( m \times λ R ) / ( n 2 R \times Pitch\_RH ) \}}^{2} ] = 1 \qquad [ Equation 20 ]$$

In Condition 18, a vertical pitch of the light-path conversion member 13 for the red color filter 12R may have a central value CPRV of Pitch_RV obtained based on Equation 21 below and may satisfy a range of about 0.8×CPRV to about 1.2×CPRV.

$$[ 1 + {( GV / CTR )}^{2} ] \times [ 1 - {\{ ( m \times λ R ) / ( n 2 R \times Pitch\_RV ) \}}^{2} ] = 1 \qquad [ Equation 21 ]$$

The solid-state imaging device 1 according to Implementation 4 may have the pixels 10 including the blue pixel 10B, the green pixel 10G, and the red pixel 10R. The horizontal width of each of the pixels 10 may be GH, and the vertical width of each of the pixels 10 may be GV. The on-chip lens 11 may have a wavelength λB of a blue area in a range of about 350 nm to about 500 nm and a refractive index of n1B in the wavelength λB, may have a wavelength λG of a green area in a range of about 500 nm to about 600 nm and a refractive index of n1G in the wavelength λG, and may have a wavelength λR of a red area in a range of about 600 nm to about 700 nm and a refractive index of n1R in the wavelength λR. The color filter 12 may include the blue color filter 12B corresponding to the blue pixel 10B and having a wavelength λB of a blue area in a range of about 350 nm to about 500 nm, a refractive index of n2B in the wavelength λB, and a thickness of CTB, the green color filter 12G corresponding to the green pixel 10G and having a wavelength λG of a green area in a range of about 500 nm to about 600 nm, a refractive index of n2G in the wavelength λG, and a thickness of CTG, and the red color filter 12R corresponding to the red pixel 10R and having a wavelength λR of a red area in a range of about 600 nm to about 700 nm, a refractive index of n2R in the wavelength λR, and a thickness of CTR, and the color filter 12 may be arranged below the on-chip lens 11 in an incident direction of the incident light L. An angle formed by a ray incident from an apex of the on-chip lens 11 to the blue color filter 12B and the normal to the apex of the on-chip lens 11 may be θB. An angle formed by a ray incident from the apex of the on-chip lens 11 to the green color filter 12G and the normal to the apex of the on-chip lens 11 may be θG. An angle formed by a ray incident from the apex of the on-chip lens 11 to the red color filter 12R and the normal to the apex of the on-chip lens 11 may be θR. Here, the light-path conversion member 13 arranged in each pixel 10 may be two-dimensionally and periodically arrayed at a pitch satisfying Condition 19 to Condition 24 described below. Also, in Equation 22 to Equation 27, m is an integer.

In Condition 19, a horizontal pitch of the light-path conversion member 13 for the blue color filter 12B may have a central value CPBH of Pitch_BH obtained based on Equation 22 below and may satisfy a range of about 0.8×CPBH to about 1.2×CPBH.

$$[ 1 + {( GH / CTB )}^{2} ] \times [ 1 - {\{ ( ( n 1 B \times SIN θ B \times Pitch\_BH ) \pm m \times λ B ) / ( n 2 B \times Pitch\_BH ) \}}^{2} ] \text{} = 1 \qquad [ Equation 22 ]$$

In Condition 20, a vertical pitch of the light-path conversion member 13 for the blue color filter 12B may have a central value CPBV of Pitch_BV obtained based on Equation 23 below and may satisfy a range of about 0.8×CPBV to about 1.2×CPBV.

$$[ 1 + {( GV / CTB )}^{2} ] \times [ 1 - {\{ ( ( n 1 B \times SIN θ B \times Pitch\_BV ) \pm m \times λ B ) / ( n 2 B \times Pitch\_BV ) \}}^{2} ] \text{} = 1 \qquad [ Equation 23 ]$$

In Condition 21, a horizontal pitch of the light-path conversion member 13 for the green color filter 12G may have a central value CPGH of Pitch_GH obtained based on Equation 24 below and may satisfy a range of about 0.8×CPGH to about 1.2×CPGH.

$$[ 1 + {( GH / CTG )}^{2} ] \times [ 1 - {\{ ( ( n 1 G \times SIN θ G \times Pitch\_GH ) \pm m \times λ G ) / ( n 2 G \times Pitch\_GH ) \}}^{2} ] \text{} = 1 \qquad [ Equation 24 ]$$

In Condition 22, a vertical pitch of the light-path conversion member 13 for the green color filter 12G may have a central value CPGV of Pitch_GV obtained based on Equation 25 below and may satisfy a range of about 0.8×CPGV to about 1.2×CPGV.

$$[ 1 + {( GV / CTG )}^{2} ] \times [ 1 - {\{ ( ( n 1 G \times SIN θ G \times Pitch\_GV ) \pm m \times λ G ) / ( n 2 G \times Pitch\_GV ) \}}^{2} ] \text{} = 1 \qquad [ Equation 25 ]$$

In Condition 23, a horizontal pitch of the light-path conversion member 13 for the red color filter 12R may have a central value CPRH of Pitch_RH obtained based on Equation 26 below and may satisfy a range of about 0.8×CPRH to about 1.2×CPRH.

$$[ 1 + {( GH / CTR )}^{2} ] \times [ 1 - {\{ ( ( n 1 R \times SIN θ R \times Pitch\_RH ) \pm m \times λ R ) / ( n 2 R \times Pitch\_RH ) \}}^{2} ] \text{} = 1 \qquad [ Equation 26 ]$$

In Condition 24, a vertical pitch of the light-path conversion member 13 for the red color filter 12R may have a central value CPRV of Pitch_RV obtained based on Equation 27 below and may satisfy a range of about 0.8×CPRV to about 1.2×CPRV.

$$[ 1 + {( GV / CTR )}^{2} ] \times [ 1 - {\{ ( ( n 1 R \times SIN θ R \times Pitch\_RV ) \pm m \times λ R ) / ( n 2 R \times Pitch\_RV ) \}}^{2} ] \text{} = 1 \qquad [ Equation 27 ]$$

As described above, the solid-state imaging device 1 according to the disclosure may include: the on-chip lens 11 having the pixel array 110 in which the plurality of pixels 10 corresponding to certain colors are two-dimensionally arranged on the chip substrate 20, the on-chip lens being configured to focus the incident light L to each of the plurality of pixels 10; the color filter 12 configured to absorb light of a predefined wavelength that is transmitted through the on-chip lens 11; the photo-electric conversion portion 14 configured to photo-electrically convert the light transmitted through the color filter 12; the light-path conversion member 13 having light transmissive properties and formed on the incident surface 12a of the color filter 12 between the on-chip lens 11 and the color filter 12; and the reflective structure 15 arranged on a lateral surface of the color filter 12, the later surface being an edge between the color filter 12 and another color filter 12 adjacent to the color filter 12, wherein the light-path conversion member 13 may include one or more diffraction elements configured to change a light path of at least the absorption light L1 of the incident light L, the absorption light L1 being absorbed by the color filter 12, toward the reflective structure 15, and the reflective structure 15 may be configured to reflect, toward the color filter 12, the absorption light L1 having the light path changed by the light-path conversion member 13, so that the absorption light L1 may have a light path length, which ensures that the absorption light L1 is absorbed by the color filter 12. That is, the reflective structure 15 may be configured to reflect, toward the color filter 12, the absorption light L1 so that the absorption light L1 can travel a physical distance within the color filter 12 that is long enough for the absorption light L1 to be fully absorbed by the color filter 12.

Therefore, the solid-state imaging device 1 may change a light path of at least the absorption light L1 from light incident, the absorption light L1 being absorbed by the corresponding color filter 12, toward a lateral surface of the color filter 12, and then, may allow the absorption light L1 to proceed to the photoelectric conversion portion 14 through the reflective structure 15. Thus, the solid-state imaging device 1 may secure a light path length for the absorption light L1 which is long enough such that the absorption light L1 may be absorbed by the color filter 12. As a result, the solid-state imaging device 1 may have a reduced device profile, because spectral properties of the color filter 12 for each pixel 10 may be secured by forming the color filter 12 thin. Also, all the devices of the solid-state imaging device 1 may have reduced device profiles due to the color filter 12 that is thinly formed, and thus, electronic devices in which the solid-state imaging device 1 is mounted may be miniaturized.

Next, a solid-state imaging device according to the disclosure is described in further detail according to implementations. However, the solid-state imaging device is not limited thereto.

A simulation for tracing rays of the solid-state imaging device according to some implementations was performed. The simulation uses Lumerical's software (Ansys product) and performs calculation using finite-difference time-domain (FDTD).

The solid-state imaging device used in the simulation has the following specifications.
1) A light-path conversion member: cylinders having a diameter of 0.2 μm and a height of 0.2 μm
2) An on-chip lens: a diameter of 1.2 μm and a thickness of 0.52 μm
3) A color filter: a thickness of 0.55 μm
4) A refractive index on the incident side: 1
5) A refractive index on the reflection side: 1.5

The light-path conversion member is arranged on the color filters at pitches of 400 nm, 500 nm, and 600 nm, respectively.

Incident light diffracts when λ/P in Equation 3 described above is greater than an incident refractive index of 1 and less than an exiting refractive index of 1.5, and does not diffract when λ/P is 1.5 or greater.

FIGS. 10A to 10I are ray trace diagrams of a solid-state imaging device. FIGS. 10A to 10I illustrate directions of incident light of each pixel and diffraction light exiting after diffraction, the directions being projected on a two-dimensional plane. Here, the horizontal axis may indicate a horizontal component of a ray and may correspond to a value obtained by multiplying a refractive index by a sine value of a horizontal angle. The vertical axis may indicate a vertical component of the ray and may correspond to a value obtained by multiplying the refractive index by a sine value of a vertical angle. On the horizontal axis, “+” indicates (+)-order light ((+)-order diffraction light), and “−” indicates (−)-order light ((−)-order diffraction light), and on the vertical axis, “+” (a + direction) indicates an incident side, and “−” (a −direction) indicates a reflection side. Broken lines may indicate a refractive index, solid lines may indicate λ/P in a horizontal direction and a vertical direction, and alternate long and short dash lines may indicate 0^{th}-order light, +1^{st}-order light, and −1^{st}-order light, respectively. FIGS. 10A to 10C are ray-trace diagrams of a blue pixel when a wavelength of incident light having an angle of incidence of 0° is 450 nm. FIG. 10A is the ray-trace diagram, in which a pitch of an array of light-path conversion member is 400 nm. FIG. 10B is the ray-trace diagram, in which the pitch of the array of the light-path conversion member is 500 nm. FIG. 10C is the ray-trace diagram, in which the pitch of the array of the light-path conversion member is 600 nm.

FIGS. 10D to 10F are ray-trace diagrams of a green pixel when a wavelength of incident light having an angle of incidence of 0° is 550 nm. FIG. 10D is the ray-trace diagram, in which a pitch of an array of light-path conversion member is 400 nm. FIG. 10E is the ray-trace diagram, in which the pitch of the array of the light-path conversion member is 500 nm. FIG. 10F is the ray-trace diagram, in which the pitch of the array of the light-path conversion member is 600 nm.

FIGS. 10G to 10I are ray-trace diagrams of a red pixel when a wavelength of incident light having an angle of incidence of 0° is 650 nm. FIG. 10G is the ray-trace diagram, in which a pitch of an array of light-path conversion member is 400 nm. FIG. 10H is the ray-trace diagram, in which the pitch of the array of the light-path conversion member is 500 nm. FIG. 10I is the ray-trace diagram, in which the pitch of the array of the light-path conversion member is 600 nm.

FIG. 11A is a schematic view of light paths of transmission light (red light) and absorption light (green light and blue light) of the red pixel having the pitch of the array of the light-path conversion member of 400 nm. The light path of each light illustrated in FIG. 11A traces each light illustrated in FIG. 10A (the blue light), FIG. 10D (the green light), or FIG. 10G (the red light). In FIG. 11A, broken lines indicate the red light, solid lines indicate the green light, and alternate long and short dash lines indicate the blue light.

As illustrated in FIG. 11A, when the pitch of the array of the light-path conversion member is 400 nm, the red light, which is the transmission light, may be allowed to proceed as straight as possible, and the green light and the blue light, which are the absorption light, may be diffracted to have a light path length, which is long enough to ensure that the absorption light is absorbed.

FIG. 11B is a schematic view of light paths of transmission light (green light) and absorption light (red light and blue light) of the green pixel having the pitch of the array of the light-path conversion member of 500 nm. The light path of each light illustrated in FIG. 11B traces each light illustrated in FIG. 10B (the blue light), FIG. 10E (the green light), or FIG. 10H (the red light). In FIG. 11B, broken lines indicate the red light, solid lines indicate the green light, and alternate long and short dash lines indicate the blue light.

As illustrated in FIG. 11B, when the pitch of the array of the light-path conversion member is 500 nm, which is middle in a range between the red pixel and the blue pixel, the green light, which is the transmission light, may be allowed to proceed as straight as possible, and the light path length of the red light may be effectively increased, and the red light and the blue light, which are the absorption light, may be diffracted to have a light path length, which is long enough to ensure that the absorption light is absorbed.

FIG. 11C is a schematic view of light paths of transmission light (blue light) and absorption light (red light and green light) of the blue pixel having the pitch of the array of the light-path conversion member of 600 nm. The light path of each light illustrated in FIG. 11B traces each light illustrated in FIG. 10C (the blue light), FIG. 10F (the green light), or FIG. 10I (the red light). In FIG. 11C, broken lines indicate the red light, solid lines indicate the green light, and alternate long and short dash lines indicate the blue light.

As illustrated in FIG. 11C, when the pitch of the array of the light-path conversion member is 600 nm, which is greater than the case of the green pixel, the blue light, which is the transmission light, may be allowed to proceed as straight as possible, and the red light and the green light, which are the absorption light, may be diffracted to have a light path length, which is long enough to ensure that the absorption light is absorbed.

As described above, as illustrated as the results of the simulation according to some implementations, in the solid-state imaging device according to the present implementations, a pitch of an array of light-path conversion member arrayed in each pixel may be formed to be appropriate for each color so that absorption light may proceed as straight as possible, and absorption light may be diffracted to have a light path having a length which is absorbable. Therefore, the solid-state imaging device according to some implementations may have a reduced device profile, because spectral properties of a color filter may be secured by forming the color filter thin.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the disclosure has been particularly shown and described with reference to implementations thereof, it will be understood that various changes in form and details may be made therein without departing from the spirit and scope of the following claims.

1. A solid-state imaging device having a pixel array comprising a plurality of pixels, the solid-state imaging device comprising, for each of the plurality of pixels:
an on-chip lens configured to focus incident light to the pixel;
a color filter configured to absorb light of a predefined wavelength that is transmitted through the on-chip lens;
a photodiode configured to photo-electrically convert the light transmitted through the color filter;
a light-path conversion member on an incident surface of the color filter between the on-chip lens and the color filter, wherein the light-path conversion member is transmissive to visible light; and
a reflector on a lateral surface of the color filter, the lateral surface defining a boundary between the color filter and an adjacent color filter,
wherein the light-path conversion member comprises a plurality of diffraction elements configured to change a light path of at least absorption light of the incident light toward the reflector, and
the reflector is arranged to reflect the absorption light toward the color filter so that the absorption light has a light path length that ensures that the absorption light is absorbed by the color filter.

2. The solid-state imaging device of claim 1, wherein
the color filter corresponds a color assigned to the pixel from among a plurality of colors assigned to the plurality of pixels,
the color filter is below the on-chip lens in an incident direction of the incident light,
the plurality of diffraction elements are arranged in a two-dimensional pattern between the on-chip lens and the color filter, and
the plurality of diffraction elements are arranged in respective arrays that correspond to the respective colors at different pitches that correspond to the respective colors.

3. The solid-state imaging device of claim 1, wherein
the plurality of pixels comprise a blue pixel, a green pixel, and a red pixel,
the color filter comprises one of a blue color filter corresponding to the blue pixel, a green color filter corresponding to the green pixel, or a red color filter corresponding to the red pixel, the color filter being below the on-chip lens in an incident direction of the incident light, and
the plurality of diffraction elements are arranged in a two-dimensional pattern between the on-chip lens and the color filter to have a different pitch for each pixel.

4. The solid-state imaging device of claim 1, wherein
the plurality of diffraction elements extend toward the on-chip lens in a direction of a normal line of the incident surface of the color filter, and
the plurality of diffraction elements are arranged periodically in a two-dimensional direction.

5. The solid-state imaging device of claim 1, wherein the pixel array comprises a first pixel and a second pixel having a same color, and wherein
a distance between the first pixel and a center of the pixel array is less than a distance between the second pixel and the center of the pixel array, and
a second pitch of an array of the plurality of diffraction elements included in the second pixel is greater than a first pitch of an array of the plurality of diffraction elements included in the first pixel.

6. The solid-state imaging device of claim 1, wherein the plurality of diffraction elements have heights set according to a focal position of a principal ray of the incident light transmitted through the on-chip lens.

7. The solid-state imaging device of claim 3, wherein the pitch of the array of the plurality of diffraction elements in each of the red pixel, the green pixel, and the blue pixel at a same image height increases in an order of the red pixel, the green pixel, and the blue pixel.

8. The solid-state imaging device of claim 3, wherein heights of the plurality of diffraction elements in each of the red pixel, the green pixel, and the blue pixel at a same image height increase in an order of the red pixel, the green pixel, and the blue pixel.

9. The solid-state imaging device of claim 1, wherein the light-path conversion member comprises a dielectric that is transmissive to visible light.

10. The solid-state imaging device of claim 1, wherein each of the plurality of diffraction elements has a contact surface with the color filter, the contact surface having at least one side that is less than 0.75 μm.

11. The solid-state imaging device of claim 1, wherein an area of a contact surface of each of the plurality of diffraction elements with the color filter is smaller than a square of 0.75 μm by 0.75 μm.

12. The solid-state imaging device of claim 1, wherein each of the plurality of diffraction elements has a size that fits within a cube of 0.75 μm by 0.75 μm.

13. The solid-state imaging device of claim 3, wherein
each of the plurality of diffraction elements in the blue color filter has a size that fits within a cube of 0.55 μm by 0.55 μm by 0.55 μm,
each of the plurality of diffraction elements in the green color filter has a size that fits within a cube of 0.65 μm by 0.65 μm by 0.65 μm, and
each of the plurality of diffraction elements in the red color filter has a size that fits within a cube of 0.75 μm by 0.75 μm by 0.75 μm.

14. The solid-state imaging device of claim 1, wherein each of the plurality of diffraction elements has a bottom area having a size defined based on a predefined wavelength corresponding to the color assigned to the pixel.

15. A solid-state imaging device comprising a pixel array comprising a plurality of pixels, wherein each pixel of the plurality of pixels comprises:
an on-chip lens configured to focus incident light;
a color filter below the on-chip lens and configured to absorb light of a first wavelength band;
a photodiode configured to photo-electrically convert the light transmitted through the color filter;
a light-path conversion member on an incident surface of the color filter between the on-chip lens and the color filter, the light-path conversion member comprising diffraction elements arrayed in a direction parallel to the incident surface; and
a reflector on a lateral surface of the color filter.

16. The solid-state imaging device of claim 15, wherein
the pixel array comprises a first pixel and a second pixel having a same color, wherein a distance between the first pixel and a center of the pixel array is less than a distance between the second pixel and the center of the pixel array, and
a pitch of an array of first diffraction elements included in the first pixel is less than a pitch of an array of second diffraction elements included in the second pixel.

17. The solid-state imaging device of claim 16, wherein heights of the first diffraction elements included in the first pixel are less than heights of the second diffraction elements included in the second pixel.

18. The solid-state imaging device of claim 16, wherein
the pixel array comprises a red pixel, a blue pixel, and a green pixel adjacent to one another, and
first diffraction elements included in the red pixel are arrayed at a first pitch,
second diffraction elements included in the green pixel are arrayed at a second pitch, and
third diffraction elements included in the blue pixel are arrayed at a third pitch,
wherein the first pitch is greater than the second pitch, and wherein the second pitch is greater than the third pitch.

19. The solid-state imaging device of claim 18, wherein heights of the first diffraction elements are greater than heights of the second diffraction elements, and the heights of the second diffraction elements are greater than heights of the third diffraction elements.

20. The solid-state imaging device of claim 15, wherein each diffraction element of the diffraction elements has a contact surface with the color filter, and a length of at least one side of the contact surface is less than 0.75 μm.
